(19) United States
(12) Patent Application Publication
(10) Pub. No.: US 2025/0338389 A1
(43) Pub. Date: Oct. 30, 2025

(54) HEAT DISSIPATION DEVICE AND ELECTRONIC EQUIPMENT

(71) Applicants: CHAMP TECH OPTICAL (FOSHAN) CORPORATION, Foshan (CN); Foxconn Technology Co., Ltd., New Taipei (TW)

(72) Inventors: MENG FU, Foshan (CN); JIN-RONG XIE, Foshan (CN)

(21) Appl. No.: 19/094,242

(22) Filed: Mar. 28, 2025

(30) Foreign Application Priority Data
Apr. 29, 2024 (CN) 202410534342.5

(51) Int. Cl. H05K 1/02

(52) U.S. Cl. CPC H05K 1/0203

(57) ABSTRACT

A heating dissipation device comprising a cooling board and two confluence connectors, wherein the cooling board is configured to attach with a thermal element, and the cooling board absorbs heat from the thermal element, and the cooling board and the thermal element are spaced apart in a first direction; the two confluence connectors are respectively connected to two opposite ends of the cooling board along a second direction, the second direction is perpendicular to the first direction; the cooling board defines a first runner, and the first runner is passed through the cooling board in the second direction; each of the two confluence connectors defines a second runner, two opposite ends of the first runner are respectively connected to two second runners of the two confluence connectors to form a cooling runner.

### FIELD

The present disclosure relates to the technical field of heat dissipation of memory storage, in particular to a heat dissipation device and an electronic equipment.

### BACKGROUND

A heat dissipation plate structure is provided to absorb heat from a memory storage. However, the heat dissipation efficiency of existing heat dissipation plate structure is low.

### BRIEF DESCRIPTION OF THE DRAWINGS

In order to illustrate the technical solutions of the embodiments of the present application more clearly, the accompanying drawings in the embodiments will be briefly introduced below. It should be understood that the following drawings only show some embodiments of the present application, and therefore should not be seen as the limiting the scope. For one of ordinary skill in the art, other related drawings can also be obtained from these drawings without any creative work.

Implementations of the present technology will now be described, by way of embodiments, with reference to the attached figures, wherein:

FIG. 1 shows a section view of an electronic equipment in an embodiment of the present disclosure.

FIG. 2 shows a schematic view of a heat dissipation device and a memory module in an embodiment of the present disclosure.

FIG. 3 shows an explosive view of the heat dissipation device and the memory module of FIG. 2.

FIG. 4 shows a schematic view of a cooling board in an embodiment of the present disclosure.

FIG. 5 shows a section view of the cooling board of FIG. 4, taken along line A-A shown in FIG. 4.

FIG. 6 shows a cross-section view of the heat dissipation device and the memory module of FIG. 2, taken along line A-A shown in FIG. 2.

FIG. 7 shows a schematic view of a confluence connector in an embodiment of the present disclosure.

FIG. 8 shows an enlarged view of a circled portion C of FIG. 4.

FIG. 9 shows a top view of a heat dissipation device and memory arranged in a base, and one of two confluence connectors is hidden.

FIG. 10 shows an enlarged view of a circled portion D of FIG. 9.

FIG. 11 shows an explosive view of a circled portion B of FIG. 2.

FIG. 12 shows a side view of the heat dissipation device and the memory module of FIG. 2, and one of two confluence connectors is hidden.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale, and the proportions of certain parts may be exaggerated to illustrate details and features better. The description is not to be considered as limiting the scope of the embodiments described herein.

Several definitions that apply throughout this disclosure will now be presented.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

The technical solutions in the embodiments of the present application will be clearly and completely described below with reference to the accompanying drawings in the embodiments of the present application. Obviously, the described embodiments are only a part of the embodiments of the present application, but not all of the embodiments.

It should be noted that when an element is referred to as being “fixed to” another element, it can be directly on the other element or intervening elements may also be present. When an element is referred to as being “connected” to another element, it can be directly connected to the other element or intervening elements may also be present. When an element is referred to as being “disposed on” another element, it can be directly disposed on the other element or intervening elements may also be present. The terms “vertical” “horizontal” “left” “right” and similar expressions are used herein for illustrative purposes only.

Unless otherwise defined, all technical and scientific terms used herein have the same meaning as commonly understood by one of ordinary skill in the art. The terms used herein in the specification of the present application are for the purpose of describing particular embodiments only, and are not intended to limit the present application. As used herein, the term “or/and” includes any and all combinations of one or more of the associated listed items.

Some embodiments of the present application are described in detail. The following embodiments and features of the embodiments may be combined with each other without conflict.

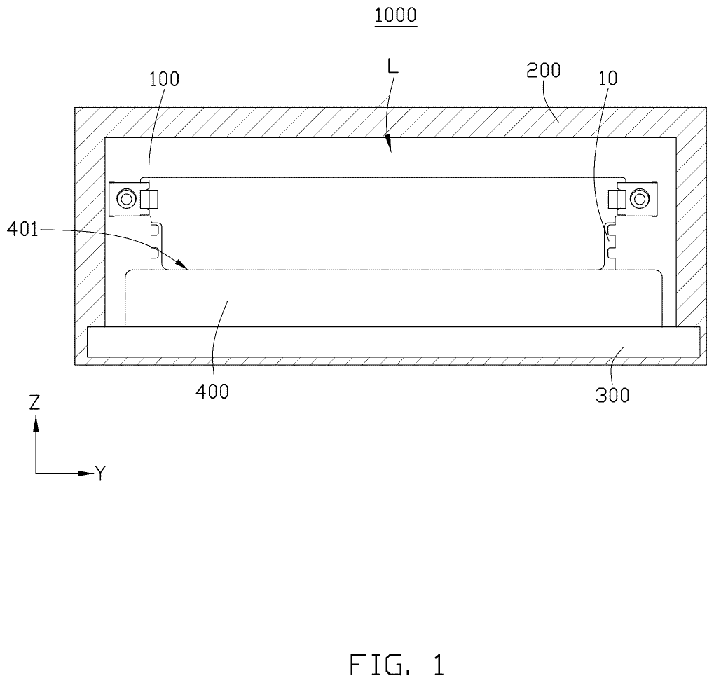

Referring to FIG. 1, an electronic device 1000 is disclosed in one embodiment. The electronic device 1000 may be a computer host.

Referring to FIG. 1, the electronic device 1000 includes a case 200, a mainboard 300, a base 400, a heat dissipation device 100, and a thermal element 10. The thermal element 10 may be any of a memory, graphics processing unit, or other electronic component that generates heat during operation. In one embodiment, the thermal element 10 is a memory. The case 200 has an installation cavity L, and the mainboard 300 is installed in the installation cavity L. The base 400 is arranged on the mainboard 300. The base 400 defines a slot 401, and the slot 401 is configured to receive the thermal element 10. The thermal element 10 has a plurality of golden fingers, and the golden fingers are plugged into the slot 401 of the base 400 in an insertion direction Z. When the thermal element 10 is inputted in the base 400, the golden fingers of the thermal element 10 is moved towards the base 400 until the golden fingers inserted in the slot 401. The thermal element 10 is electric connected to the mainboard 300 via the golden fingers.

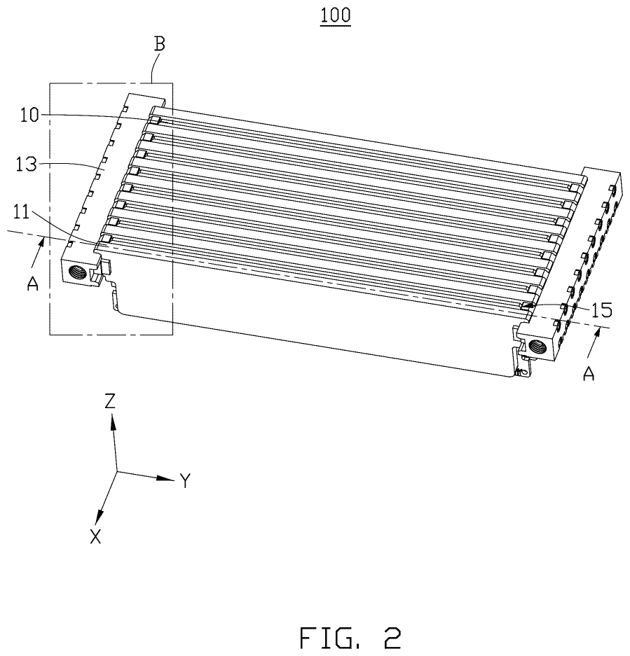

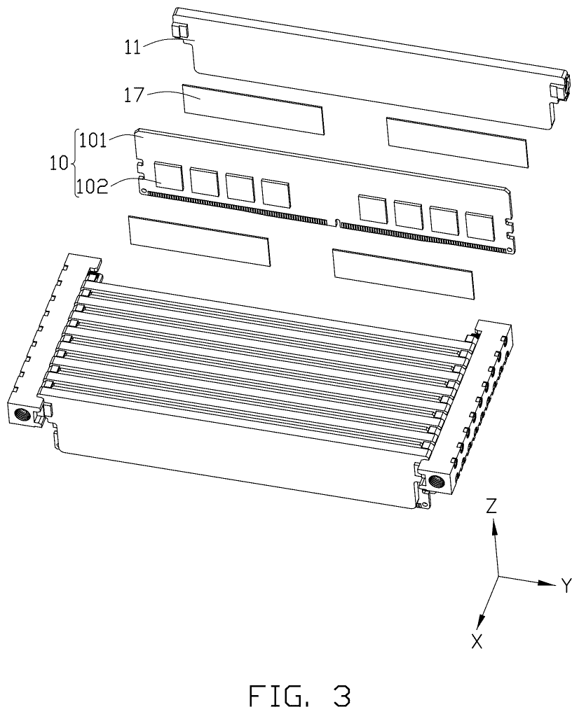

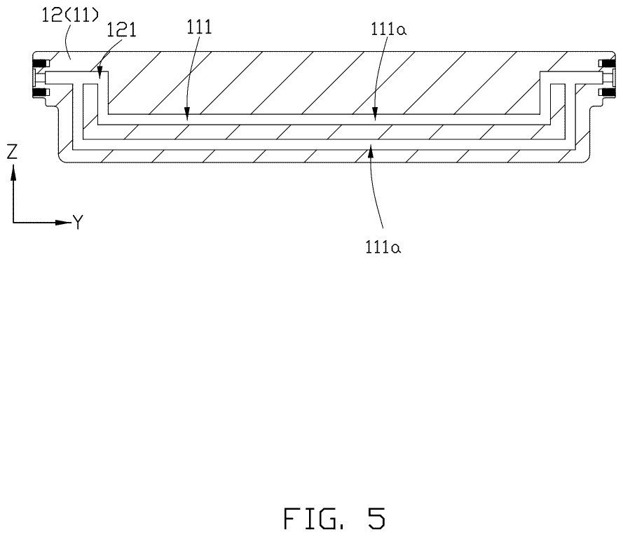

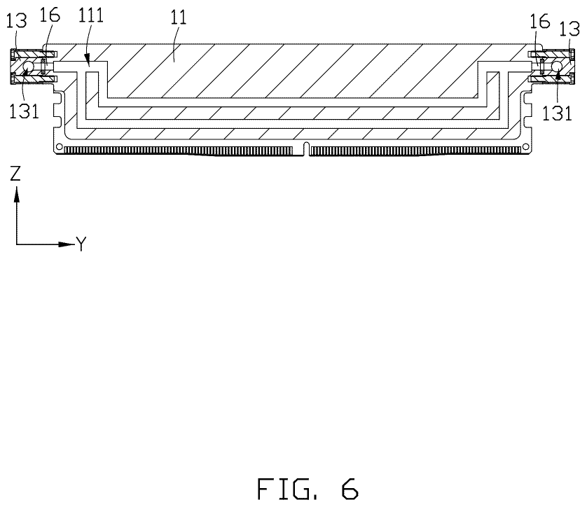

Referring to FIG. 2 and FIG. 3, in one embodiment, the heat dissipation device 100 includes one or more cooling board 11 and two confluence connectors 13. The one or more cooling board 11 and the thermal element 10 are arranged in a first direction X. Each of the two confluence connectors 13 is extended in the first direction X. The cooling board 11 is extended in a second direction Y The second direction Y is perpendicular to the first direction X. The insertion direction Z is perpendicular to each of the first direction X and the second direction Y The one or more cooling board 10 is attached to a thermal element 10, and the one or more cooling board 11 absorbs heat from the thermal element 10. The two confluence connectors 13 are respectively connected to two opposite ends of the one or more cooling board 11 along the second direction Y Referring to FIG. 5, each of the one or more cooling board 11 defines a first runner 111, and the first runner 111 extends through a corresponding cooling board 11 of the one or more cooling board 11 in the second direction Y Referring to FIG. 6, each of the two confluence connectors 13 defines a second runner 131, the second runner 131 is passed through the confluence connector 13 in the first direction X. Two opposite ends of the first runner 111 are respectively connected to the corresponding second runner 131 of each of the two confluence connectors 13 to form a cooling runner 16.

In one embodiment, referring to FIG. 5, the first runner 111 includes two third runners 111a. The two third runners 111a are parallel to the second direction Y, and corresponded to the thermal element 10 in the first direction X. This increases a heat dissipation area of the first runner 111. In other embodiment, quantity of the first runner 111 is multiple, or a cross-section width of the first runner 111 is greater than a width of the chip 102.

In one embodiment, referring to FIG. 5, the one or more cooling board 11 includes two first boards 12. A side of each of the two first boards in the second direction Y 12 is provided with a first board groove 121. The two first boards 12 are welded to each other, and the first board groove 121 of a first board 12 of the first boards 12 communicates to the first board groove 121 of another first board 12 of the two first boards 12 to form the first runner 111.

Referring to FIG. 3, in one embodiment, the thermal element 10 includes a circuit board 101 and chips 102. The chips 102 arranged at two opposite sides of the circuit board 101, and the chips 102 are electrically connected with the circuit board 101. The heat dissipation device 100 further includes a heat conducting plate 17. The heat conducting plate 17 is configured to connect the one or more cooling board 11 and a chip 102 of the thermal element 10. The heat conducting plate 17 is arranged on a side of the cooling board 11 facing the chip 102 in the first direction X. The heat conducting plate 17 is corresponded to the chip 102 in the first direction X. The chips 102 attach the heat conducting plate 17 when the thermal element 10 is inputted in the base 400, and heat generated from the chips 102 is absorbed by the heat conducting plate 17.

In one embodiment, the heat conducting plate 17 is made of colloidal material. In another embodiment, the heat conducting plate 17 may be made of other material with better heat conducting property.

In one embodiment, referring to FIG. 3 and FIG. 6, a part of an orthographic projection of the first runner 111 onto the heat conducting plate 17 coincides with the heat conducting plate 17, therefore improving heat transfer efficiency between the first runner 111 and the heat conducting plate 17.

In one embodiment, the heat conducting plate 17 can be slightly deformation to attach the chip 102 and the cooling board 11, this improving heat absorb efficiency between the heat conducting plate 17, the cooling board 11 and the chip 102.

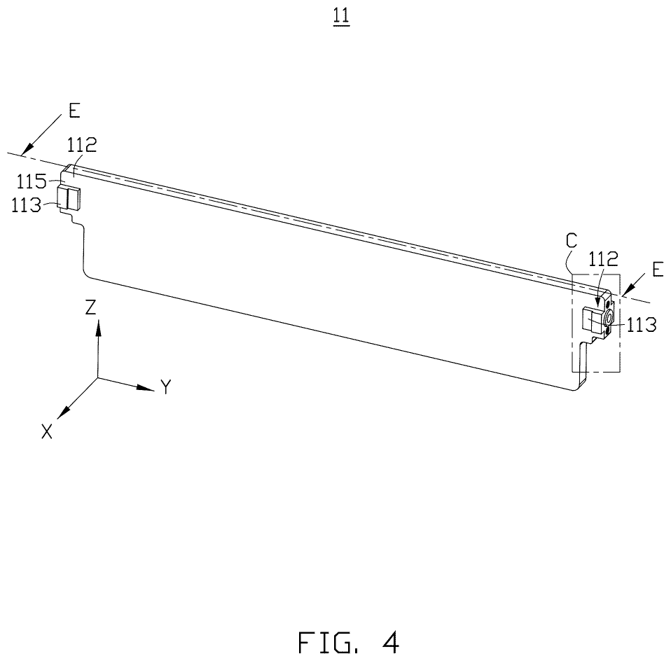

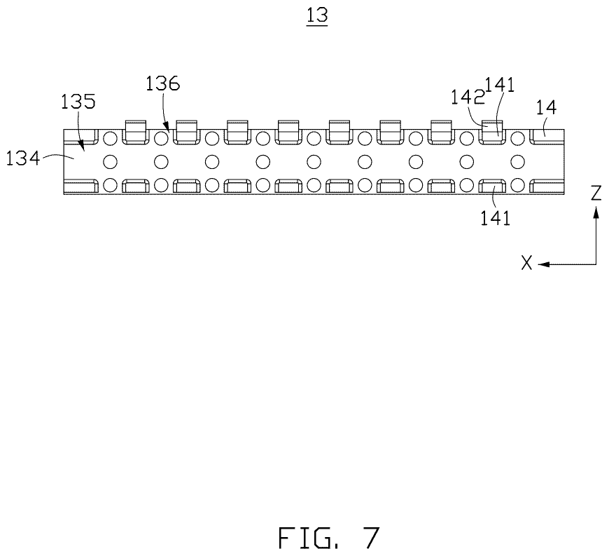

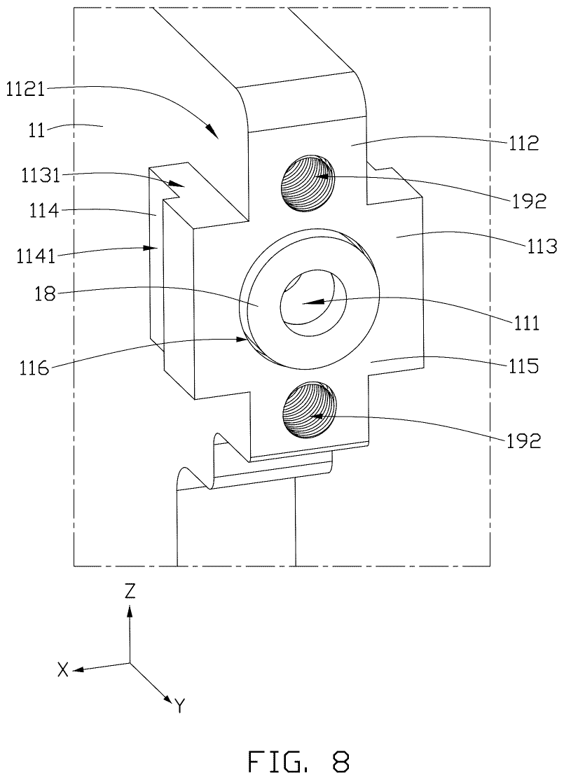

In one embodiment, referring to FIG. 4, FIG. 7 and FIG. 8, a position convex portion 115 is provided at each of the two opposite ends of the one or more cooling board 11 in the second direction Y. A position groove 134 is defines at a side of each of the two confluence connectors 13 facing the one or more cooling board 11. The position convex portion 115 is received in the position groove 134 of a corresponding confluence connector 13 to the two confluence connectors 13. Therefore, two position convex portions 115 of two opposite ends of the cooling board 11 are respectively connected to two corresponding confluence connectors 13.

In one embodiment, referring to FIG. 4, FIG. 7 and FIG. 8, two opposite ends 112 of each of the cooling board 11 extend in the second direction Y Side convex portions 113 are provided at two opposite sides of the two opposite ends 112 of the cooling board 11, and the side convex portions 113 extend in the first direction X. The position convex portion 115 is cross-shaped and is formed by each of the two opposite ends 112 respectively combining with the side convex portions 113. The position groove 134 includes a first groove 135 and a plurality of second grooves 136. The first groove 135 is strip-shaped extending in the first direction X. Each of the plurality of second grooves 136 is strip-shaped extending in the insertion direction Z. The plurality of second grooves 136 is spaced apart in the first direction X. Each of the plurality of second grooves 136 is intersected with the first groove 135 to form a cross shaped portion. The side convex portion 113 is received in the first groove 135, each of the two opposite ends 112 of each of the plurality of cooling boards 11 is received in a corresponding second groove 136 of the plurality of second grooves 136.

Each of the plurality of cross-shaped position convex portions 115 is received in a corresponding cross-shaped portion of the position groove 134.

Referring to FIG. 8, an end 112 of the position convex portion 115 has a first against surface 1121 in the first direction X. The first against surface 1121 abuts against surfaces of one of the plurality of second grooves 136 in the first direction X. Each of the side convex portion 113 has second against surfaces 1131 in an insertion direction Z. The second against surfaces 1131 abut against surfaces of the first groove 135 in the insertion direction Z. Therefore, the cooling board 11 is limited in the first direction X and the insertion direction Z via a cooperation between the cross-shaped position convex portion 115 and the cross-shaped position groove 134.

In one embodiment, an end surface of the side convex portion 113 in the second direction Y is coplanar with an end surface of the end 112 in the second direction Y A subface of the first groove 135 is coplanar with a subface of the second groove 136, this improving bonding effect between the cooling board 11 and the confluence connector 13.

In one embodiment, in a step of processing the plurality of second grooves 136, surfaces of the plurality of second grooves 136 in the first direction X is parallel, this reducing processing error of the plurality of second grooves 136.

In one embodiment, referring to FIG. 4, FIG. 7 and FIG. 8, part of each of the two confluence connectors 13 facing the plurality of cooling boards 11 is divided into two convex strips 14 by the first groove 135. The two convex strips 14 are located on two opposite sides of the first groove 135 in the insertion direction Z. The two convex strips 14 are divided into a plurality of convex lumps 141 by the plurality of second grooves 136. The plurality of convex lumps 141 is spaced apart in the first direction X. Each of the ends 112 of each of the plurality of cooling boards 11 is positioned between two adjacent convex lumps 141 of the plurality of convex lumps 141 in the first direction X, each of the side convex portions 113 is positioned between the two adjacent convex lumps 141 in an insertion direction Z.

The plurality of convex lumps 141 is arranged on two opposite sides of the second groove 136 in the first direction X. A side surface of one of the plurality of convex lumps 141 in the first direction X abuts against with the cooling board 11. A bottom surface of the convex lump 141 facing the side convex portion 113 in the insertion direction Z abuts against a surface of the side convex portion 113. Four corners of each position convex plate 115 are clamped via four convex lumps 141. Two adjacent convex lumps 141 of the four convex lumps 141 in the first direction X respectively against the end 112 to restrict movement of the cooling board 11 in the first direction X. Two adjacent convex lumps 141 of the four convex lumps 141 in the insertion direction Z respectively against the side convex portion 113 to restrict movement of the cooling board 11 in the insertion direction Z.

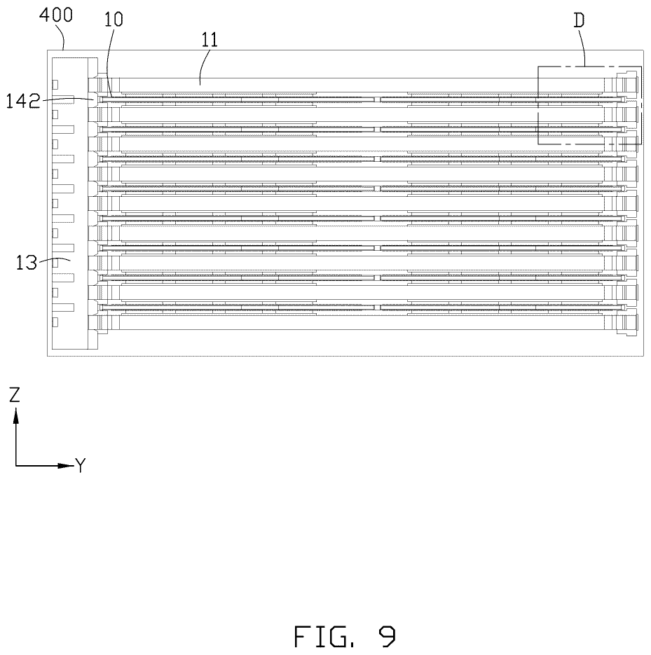

In one embodiment, referring to FIG. 7 to FIG. 9, each of the plurality of convex lumps 141 away from the thermal element 10 in the insertion direction Z is provided with an against part 142, and the against part 142 extends towards the thermal element 10 in the second direction Y When the thermal element 10 is inputted in the base 400, the against part 142 is above the thermal element 10, and the against part 142 abuts against the thermal element 10 in the insertion direction Z.

When the thermal element 10 is inserted in the base 400 in the insertion direction Z. The against part 142 attach a upside of the thermal element 10 in the insertion direction Z, and the thermal element 10 is limited via the against part 142 in the insertion direction Z. This preventing the thermal element 10 from escaping from the base 400, and the against part 142 has small size and less installation space.

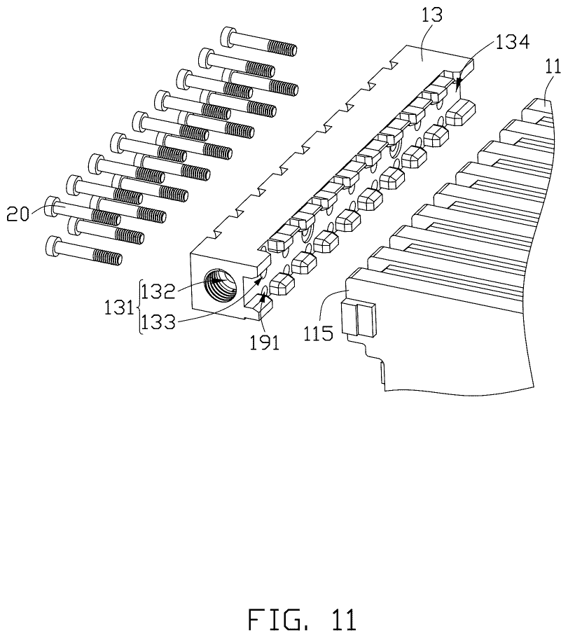

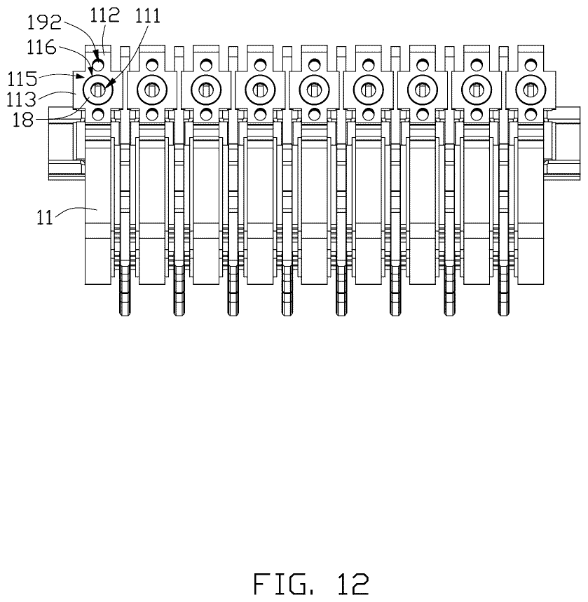

In one embodiment, referring to FIG. 11 and FIG. 12, the second runner 131 includes a first hole 132 and a plurality of second holes 133. Each of the plurality of second holes 133 communicates with the first hole 132. The plurality of first grooves 135 is respectively communicated to a corresponding second hole 133 of the plurality of second holes 133. Two ends of the first runner 111 radially expand to form a receiving groove 116. The heat dissipation device 100 further includes two sealing elements 18. Each of the two sealing elements 18 is respectively received in the receiving groove 116, and each of the sealing elements 18 is positioned between the cooling board 10 and a corresponding confluence connector 13 of the two confluence connectors 13.

Each of the two confluence connectors 13 is connected to the cooling board 10 via a screw 20, and each of the two sealing elements 18 is squeezed by the screw 20 connected to the corresponding confluence connector 13.

In one embodiment, referring to FIG. 11, the position convex portion 115 is further arranged on one side of the one or more cooling board 11 and connected to the corresponding confluence connector 12 in the position groove 134 via two screws 20. the position convex portion 115 is connected to a corresponding position groove 134 via two screws 20. The two screws 20 are respectively arranged on two sides of the position convex portion 115 in the insertion direction Z. The screw 20 is extended in the second direction Y Two ends of the cooling board 11 are respectively connected to the two confluence connectors 13 via the screw 20, the thermal element 10 is limited by the confluence connectors 13 in the second direction Y.

In one embodiment, referring to FIG. 11 and FIG. 12, the sealing element 18 is a sealing ring. A thickness of the sealing element 18 is larger than a depth of the receiving groove 116. Each of two ends 112 of the thermal element 10 defines a first threaded hole 191 and a second threaded hole 192. The first threaded hole 191 and the second threaded hole 192 are spaced apart in the second direction Y The heat dissipation device further includes a plurality of screws 20. Two ends 112 of the cooling board 11 are respectively connected with two corresponding confluence connectors 13 via two corresponding of the plurality of screws 20. Two screws 20 of the plurality of screws 20 are respectively received in the first threaded hole 191 and the second threaded hole 192. The plurality of screws 20 are connected between the confluence connector 13 and the cooling board 11. The two screws 20 of the plurality of the screws 20 squeeze a corresponding sealing element 18. The sealing element 18 can change shape and fill gaps between the screw 20 and the confluence connector 13 under an action of external force, to achieve a reliable sealing effect.

In other embodiment, the sealing element 18 may be sealant or other sealing materials for pipe seal. A sealing joint between the cooling board 11 and the confluence connector 13 is sealed via the sealing element 18.

In one embodiment, the electronic device 1000 includes a plurality of thermal elements 10. The thermal elements 10 may be memories. The heat dissipation device 100 includes a plurality of cooling boards 11. The plurality of cooling boards 11 is spaced apart along the first direction X. A receiving space 15 is defined between any two adjacent cooling boards 11. The receiving space 15 is configured to receive the thermal element 10, and the cooling board 11 absorbs heat from the thermal element 10. Each of the plurality of cooling boards 11 has a first runner 111. Each of the plurality of cooling boards 11 is received in a corresponding receiving space 15. The two confluence connectors are respectively connected to two opposite ends of each of the plurality of cooling boards 11 along the second direction Y.

The second runner 131 and the first runner 111 communicate with each other at a junction between the two confluence connectors 13 and the cooling board 11, and a cooling runner 16 is formed by the second runner 131 and the first runner 111. Two opposite ends of each of the plurality of first runners 111 are communicated connected to the two second runners 131 of the two confluence connectors 13, and the cooling runner 16 is formed by the plurality of first runners 111 with the two second runners 131.

In one embodiment, the receiving space 15 is further configured to receive the thermal element 10 in the first direction X and adjacent to the two adjacent cooling boards 11.

In one embodiment, the plurality of side convex portions 113 is received in the first groove 135, and each of the plurality of ends 112 is received in a corresponding second groove 136. Therefore, the confluence connector 13 can simultaneously limit the plurality of cooling boards 11 in the first direction X and the insertion direction Z.

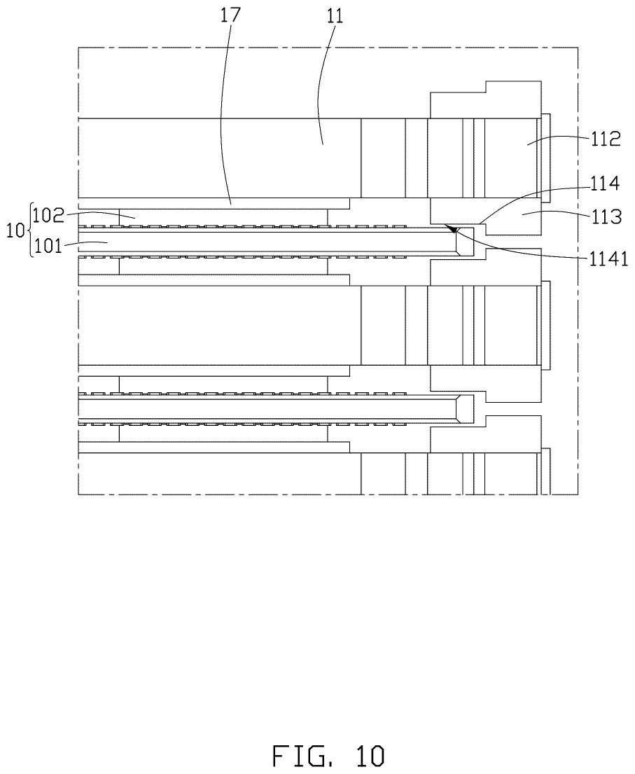

In one embodiment, referring to FIG. 8 to FIG. 10, each of the side convex portions 113 is provided with a matching groove 114 at one side of a corresponding convex portion 113 of the side convex portions 113 away from the end 112 of each of the plurality of cooling boards 11. An inner surface of the matching groove 114 is away from the cooling boards 11. Two adjacent matching grooves 114 of two adjacent cooling boards 11 of the one or more cooling board 11 clamp a part of the thermal element 10. Two opposite inner surfaces of opposite two of the matching grooves 114 abut against the thermal element 10.

In conclusion, the thermal element 10 is installed in the receiving space 15, the receiving space 15 is defined by the cooling board 11 and the confluence connector 13, and the cooling runner 16 formed by the first runner 111 in the cooling board 11 and the second runner 131 in the confluence connector 13 can improve heat dissipation efficiency of the thermal element 10. The heat dissipation device 100 can install a plurality of memory modules 10 at the same time, and the plurality of memory modules 10 is easy to disassemble and install.

The above embodiments are only used to illustrate the technical solutions of the present application rather than limitations. Although the present application has been described in detail with reference to the above preferred embodiments, one of ordinary skill in the art should understand that the technical solutions of the present application may be modified or equivalently replaced without departing from the spirit and scope of the technical solutions of the present application.

What is claimed is:

1. A heating dissipation device comprising one or more cooling board and two confluence connectors, wherein the one or more cooling board is attached to a thermal element, and the one or more cooling board absorbs heat from the thermal element, and the one or more cooling board and the thermal element are arranged in a first direction;
the two confluence connectors are respectively connected to two opposite ends of the one or more cooling board along a second direction, the second direction is perpendicular to the first direction;
each of the one or more cooling board defines a first runner, and the first runner extends through a corresponding cooling board of the one or more cooling board in the second direction; each of the two confluence connectors defines a second runner, two opposite ends of the first runner are respectively connected to the second runner of each of the two confluence connectors to form a cooling runner.

2. The heat dissipation device of claim 1, wherein a position convex portion is provided at each of the two opposite ends of the one or more cooling board in the second direction;
a position groove is defined at a side of each of the two confluence connectors facing the one or more cooling board;
the position convex portion is received in the position groove of a corresponding confluence connector to the two confluence connectors.

3. The heat dissipation device of claim 2, the heat dissipation device comprising a plurality of cooling boards, wherein two opposite ends of each of the plurality of cooling boards extend in the second direction; side convex portions are provided at two opposite sides of each of the two opposite ends of the plurality of cooling boards, and the side convex portions extend in the first direction;
the position convex portion is cross-shaped and is formed by each of the two opposite ends respectively combining with the side convex portions;
the position groove comprises a first groove and a plurality of second grooves;
the first groove is strip-shaped extending in the first direction, and each of the plurality of second grooves is strip-shaped extending in the second direction;
the plurality of second grooves is spaced apart in the first direction, and each of the plurality of second grooves intersects the first groove to form a cross shaped portion;
the side convex portion is received in the first groove, each of the two opposite ends of each of the plurality of cooling boards is received in a corresponding second groove of the plurality of second grooves.

4. The heat dissipation device of claim 3, wherein an end of the position convex portion has a first against surface in the first direction, the first against surface abuts against surfaces of one of the plurality of second grooves in the first direction;
each of the side convex portions has second against surfaces in an insertion direction, the second against surfaces abut against surfaces of the first groove in the insertion direction, the insertion direction is perpendicular to each of the first direction and the second direction.

5. The heat dissipation device of claim 3, wherein the position convex portion is further arranged on one side of the one or more cooling board and connected to the corresponding confluence connector in the position groove via two screws; the two screws are respectively arranged at two sides of the position convex portion in an insertion direction; the two screws are extended in the second direction.

6. The heat dissipation device of claim 3, wherein each of the side convex portions is provided with a matching groove at one side of a corresponding convex portion of the side convex portions away from the end of each of the plurality of cooling boards;
an inner surface of the matching groove is away from the cooling boards, two adjacent matching grooves of two adjacent cooling boards of the one or more cooling board clamp a part of the thermal element, and two opposite inner surfaces of opposite two of the matching grooves abut against the thermal element.

7. The heat dissipation device of claim 3, wherein part of each of the two confluence connectors facing the plurality of cooling boards is divided into two convex strips by the first groove, and the two convex strips are located at two opposite sides of the first groove;
the two convex strips are divided into a plurality of convex lumps by the plurality of second grooves, and the plurality of convex lumps is spaced apart in the first direction;
each of the end of each of the plurality of cooling boards is positioned between two adjacent convex lumps of the plurality of convex lumps in the first direction, each of the side convex portions is positioned between the two adjacent convex lumps in an insertion direction, the insertion direction is perpendicular to each of the first and the second directions;
each of the plurality convex lumps away from the thermal element in the insertion direction is provided with an against part, and the against part extends towards the thermal element in the second direction; the against part abuts against the thermal element in the insertion direction.

8. The heat dissipation device of claim 1, wherein
the heat dissipation device further comprising a heat conducting plate, the heat conducting plate is configured to connect the one or more cooling board to a chip of the thermal element.

9. The heat dissipation device of claim 8, wherein a part of an orthographic projection of the first runner onto the heat conducting plate in the first direction coincides with the heat conducting plate.

10. The heat dissipation device of claim 1, wherein the second runner comprises a first hole and a plurality of second holes, each of the plurality of second holes communicates with the first hole, a plurality of first grooves is respectively communicated to a corresponding second hole of the plurality of second holes;
two ends of the first runner radially expand to form a receiving groove;
the heat dissipation device further comprises two sealing elements, each of the two sealing elements is respectively received in the receiving groove, and each of the two sealing elements is positioned between the cooling board and a corresponding confluence connector of the two confluence connectors.

11. The heat dissipation device of claim 10, wherein each of the two confluence connectors is connected to the cooling board via a screw, and each of the two sealing elements is squeezed by the screw connected to the corresponding confluence connector.

12. The heat dissipation device of claim 1, wherein the one or more cooling board comprises two first boards, a side of each of the two first boards in the second direction is provided with a first board groove;
the two first boards are welded to each other, and the first board groove of a first board of the two first boards communicates to the first board groove of another first board of the two first boards to form the first runner.

13. The heat dissipation device of claim 1, wherein the second runner and the first runner communicate with each other at a junction between the two confluence connectors and the cooling board, and a cooling runner is formed by the second runner and the first runner.

14. The heat dissipation device of claim 1, wherein the first runner comprises two third runners, the two third runners are parallel to the second direction and correspond to the thermal element in the first direction.

15. The heat dissipation device of claim 1, wherein the heat dissipation device comprising a plurality of cooling boards, the plurality of cooling boards is spaced apart along the first direction, and a receiving space is defined between each two adjacent cooling boards of the plurality of cooling boards, the receiving space is configured to receive the thermal element, and the plurality of cooling boards is configured to absorb heat from the thermal element;
the cooling runner is formed by the first runners and the two second runners.

16. The heat dissipation device of claim 15, wherein the receiving space is further configured to receive the thermal element in the first direction and adjacent to the two adjacent cooling boards.

17. An electronic equipment comprising:
a mainboard;
a base arranged on the mainboard;
a thermal element; and
a heat dissipation device comprising:
one or more cooling board and two confluence connectors, wherein the cooling board attaches with the thermal element, and the cooling board absorbs heat from the memory module, and the cooling board and the thermal element are arranged in a first direction;
the two confluence connectors are respectively connected to two opposite ends of the cooling board along a second direction, the second direction is perpendicular to the first direction;
the cooling board defines a first runner, and the first runner is passed through the cooling board in the second direction; each of the two confluence connectors defines a second runner, two opposite ends of the first runners are respectively connected to two second runners of the two confluence connectors to form a cooling runner.

18. The electronic equipment of claim 17, wherein a position convex portion is provided at each end of the cooling board in the second direction;
a position groove is defined at a side of each confluence connector facing the cooling board;
each of the position convex portion is received in a corresponding position groove.

19. The electronic equipment of claim 18, wherein the heat dissipation device further comprises a plurality of cooling boards, the plurality of cooling boards is provided with ends extending in the second direction; side convex portions are provided at two opposite sides of each of the ends, and side convex portions extending in the first direction;
a cross-shaped position convex portion is formed by each of the ends combined with the side convex portions;
the position groove comprises a first groove and a plurality of second grooves;
the first groove is a first strip groove extending in the first direction, and each of the plurality of second grooves is a second strip groove extending in the second direction;
the plurality of second grooves is spaced apart in the first direction, and each of the plurality of second grooves intersects the first groove to form a cross shaped portion;
the side convex portion is received in the corresponding first groove, each of the ends is respectively received in a corresponding second groove.

20. The electronic equipment of claim 18, wherein part of each confluence connector facing the plurality of cooling boards is divided into two convex strips by the first groove, and the two convex strips are located at two opposite sides of the first groove;
the two convex strips are divided into a plurality of convex lumps by the second groove, and the plurality of convex lumps is spaced apart in the first direction;
each of the ends is positioned between two adjacent convex lumps in the first direction, each of the side convex portions is positioned between two adjacent convex lumps in an insertion direction, the insertion direction is perpendicular to the first direction, and the insertion direction is perpendicular to the second direction;
each of the plurality convex lumps away from the memory module in the insertion direction is provided with an against part, and the against part is extended towards the thermal element in the second direction; the against part abuts against the memory in the insertion direction.
